(19) United States
(12) Patent Application Publication
(10) Pub. No.: US 2026/0238197 A1
(43) Pub. Date: Aug. 13, 2026

(54) POWER CONVERTER CURRENT SENSE OFFSET CORRECTION CIRCUIT

(71) Applicant: TEXAS INSTRUMENTS INCORPORATED, Dallas, TX (US)

(72) Inventors: Mustapha El-Markhi, Richardson, TX (US); Bikash Pradhan, Bangalore (IN); Avadhut Junnarkar, McKinney, TX (US); Roland Son, Richardson, TX (US)

(21) Appl. No.: 19/284,354

(22) Filed: Jul. 29, 2025

Related U.S. Application Data
(60) Provisional application No. 63/757,827, filed on Feb. 13, 2025.

(51) Int. Cl. H03K 5/003; H02M 1/00; H02M 3/07; H03F 3/00

(52) U.S. Cl. CPC H03K 5/003; H02M 3/07; H03F 3/005; H02M 1/0009

(57) ABSTRACT

Described embodiments include a circuit comprising a controller having four outputs. A switched capacitor circuit includes a first switch having a first terminal coupled to the output of an amplifier and a control terminal coupled to the first output of the controller. A second switch has a first terminal coupled to the first switch and a control terminal coupled to the second output of the controller. A third switch has a first terminal coupled to the output of the amplifier and a control terminal coupled to the third output of the controller. A fourth switch has a first terminal coupled to the third switch, a control terminal coupled to the fourth output of the controller, and a second terminal coupled to the second switch. A first capacitor is coupled to the second switch and ground. A second capacitor is coupled to the fourth switch and ground.

### CROSS-REFERENCE TO RELATED APPLICATION

This application claims priority to U.S. Provisional Patent Application No. 63/757,827 filed Feb. 13, 2025, which is incorporated herein by reference in its entirety.

### BACKGROUND

This description relates to offset correction circuits such as may be used in a current sense circuit for a power converter. In an example system, the current is sensed through the low side field effect transistor (FET). For example, periodically (e.g. every eighth PWM cycle), with the low side FET turned on, an auto-zero offset calibration cycle is activated to perform an offset correction. At the completion of the auto-zero cycle, the offset information can be stored as a voltage across a capacitor, and that offset information used during the next period to correct or cancel out the offset in the current sense circuit. Maintaining accurate offset information allows other circuitry in the power converter to accurately operate.

### SUMMARY

In a first example, a circuit comprises a controller having first, second, third and fourth outputs. An amplifier has first and second inputs and an output. A switched capacitor circuit includes a first switch having first and second terminals and a control terminal. The first terminal of the first switch is coupled to the output of the amplifier. The control terminal of the first switch is coupled to the first output of the controller. A second switch has first and second terminals and a control terminal. The first terminal of the second switch is coupled to the second terminal of the first switch. The control terminal of the second switch is coupled to the second output of the controller.

A third switch has first and second terminals and a control terminal. The first terminal of the third switch is coupled to the output of the amplifier. The control terminal of the third switch is coupled to the third output of the controller. A fourth switch has first and second terminals and a control terminal. The first terminal of the fourth switch is coupled to the second terminal of the third switch. The control terminal of the fourth switch is coupled to the fourth output of the controller, and the second terminal of the fourth switch is coupled to the second terminal of the second switch. A first capacitor has a first terminal coupled to the first terminal of the second switch and a second terminal coupled to a ground terminal. A second capacitor has a first terminal coupled to the first terminal of the fourth switch and a second terminal coupled to the ground terminal.

In a second example, a circuit comprises a controller having first, second, third and fourth outputs. A first amplifier has first and second inputs and an output. The first input is coupled to a voltage terminal. A switched capacitor circuit includes a first switch having first and second terminals and a control terminal. The first terminal of the first switch is coupled to the output of the first amplifier. The control terminal of the first switch is coupled to the first output of the controller. A second switch has first and second terminals and a control terminal. The first terminal of the second switch is coupled to the second terminal of the first switch. The control terminal of the second switch is coupled to the second output of the controller.

A third switch has first and second terminals and a control terminal. The first terminal pf the third switch is coupled to the output of the first amplifier. The control terminal of the third switch is coupled to the third output of the controller. A fourth switch has first and second terminals and a control terminal. The first terminal of the fourth switch is coupled to the second terminal of the third switch. The control terminal of the fourth switch is coupled to the fourth output of the controller, and the second terminal of the fourth switch is coupled to the second terminal of the second switch.

A first capacitor has a first terminal coupled to the first terminal of the second switch and a second terminal coupled to a ground terminal. A second capacitor has a first terminal coupled to the first terminal of the fourth switch and a second terminal coupled to the ground terminal. A second amplifier has an input and an output. The input of the second amplifier is coupled to the second terminal of the fourth switch. A third amplifier has an input and an output. The input of the third amplifier is coupled to the voltage terminal. A subtractor has first and second inputs and an output. The first input of the subtractor is coupled to the output of the second amplifier. The second input of the subtractor is coupled to the output of the third amplifier. A fourth amplifier has an input and an output. The input of the fourth amplifier is coupled to the output of the subtractor. The output of the subtractor is coupled to the second input of the first amplifier.

In a third example, a system comprises a multiphase voltage regulation controller having an input and multiple outputs. The system has multiple power stages, each respective power stage having an input and an output. Each respective power stage input is coupled to a respective output of the multiphase voltage regulation controller. Each respective power stage includes a controller having first, second, third and fourth outputs. An amplifier has first and second inputs and an output. A switched capacitor circuit includes a first switch having first and second terminals and a control terminal. The first terminal of the first switch is coupled to the output of the amplifier. The control terminal of the first switch is coupled to the first output of the controller. A second switch has first and second terminals and a control terminal. The first terminal of the second switch is coupled to the second terminal of the first switch. The control terminal of the second switch is coupled to the second output of the controller.

A third switch has first and second terminals and a control terminal. The first terminal of the third switch is coupled to the output of the amplifier. The control terminal of the third switch is coupled to the third output of the controller. A fourth switch has first and second terminals and a control terminal. The first terminal is coupled to the second terminal of the third switch. The control terminal of the fourth switch is coupled to the fourth output of the controller. The second terminal of the fourth switch is coupled to the second terminal of the second switch. A first capacitor has a first terminal coupled to the first terminal of the second switch and a second terminal coupled to a ground terminal. A second capacitor has a first terminal coupled to the first terminal of the fourth switch and a second terminal coupled to the ground terminal. Multiple inductors each have a first terminal and a second terminal. Each respective first inductor terminal is coupled to a respective output of a power stage. A processor has an input coupled to each of the respective second terminals of the multiple inductors.

### BRIEF DESCRIPTION OF THE DRAWINGS

FIG. 1 shows a block diagram for an example power converter circuit.

FIG. 2 shows a schematic diagram for an example analog front end (AFE) circuit.

FIG. 3 shows a schematic diagram for an example auto-zero capacitor circuit.

FIG. 4 shows a schematic diagram for an example logic circuit included in a controller circuit for an auto-zero capacitor circuit.

FIG. 5 shows a schematic diagram for an example logic circuit included in a controller circuit for an auto-zero capacitor circuit.

FIG. 6 shows a logic truth table for an example auto-zero capacitor circuit.

FIG. 7 shows a flow diagram for an example process for operating a current sense circuit using an auto-zero capacitor circuit.

FIG. 8 shows a timing diagram for an example auto-zero capacitor circuit during normal operation with a constant load.

FIG. 9 shows a timing diagram for an example auto-zero capacitor circuit during a load transient event.

FIG. 10 shows a block diagram for an example power supply system with multiphase DC-DC converters.

FIG. 11 shows a block diagram for an example multiphase power converter system.

### DETAILED DESCRIPTION

In this description, the same reference numbers depict same or similar (by function and/or structure) features. The drawings are not necessarily drawn to scale.

Having accurate current sense information in systems such as power converters can be useful because it allows current limits to be set more precisely. A load transient demanding higher current can cause an undershoot in the output voltage. In response to that output voltage undershoot, the controller may issue PWM pulses in quick succession to bring the output voltage level back up more quickly.

The examples described herein relate to offset correction circuits such as may be used in a current sense circuit for a power converter. However, the described examples may also relate to other systems having an offset correction or auto-zero calibration circuit. In an example system having a current sense circuit, the current is sensed through a low side field effect transistor (FET). The current may be sensed by sensing the voltage (V_{DS}) across a FET having a known drain-to-source resistance (R_{DSon}).

For example, periodically (e.g. every eighth cycle), while the low side FET is turned on, an auto-zero cycle can be commenced to perform an offset voltage correction. At the completion of the auto-zero cycle, the offset voltage can be stored as a voltage across a capacitor, and that offset voltage applied to the current sense circuit during the next period to correct or cancel out the offset in the current sense circuit.

A potential problem can occur in the autozero circuit as a result of a load transient, which can occur in a power converter when a load is either added or removed at the output voltage terminal leading to either higher or lower current demand from the power converter. A load transient demanding higher current can cause an undershoot in the output voltage. In response to that voltage undershoot, voltage regulation controller circuit may issue PWM pulses in quick succession to bring the output voltage level back up more quickly.

If a load transient occurs during an auto-zero cycle, the auto-zero cycle may terminate prematurely, preventing the capacitor that is storing the offset information from fully charging. A potential consequence of this is that the voltage across the capacitor storing the offset information may not store the correct value to cancel the offset in the circuit. This may lead to use of a wrong offset voltage for the next time period until the next cycle when the offset voltage can be corrected.

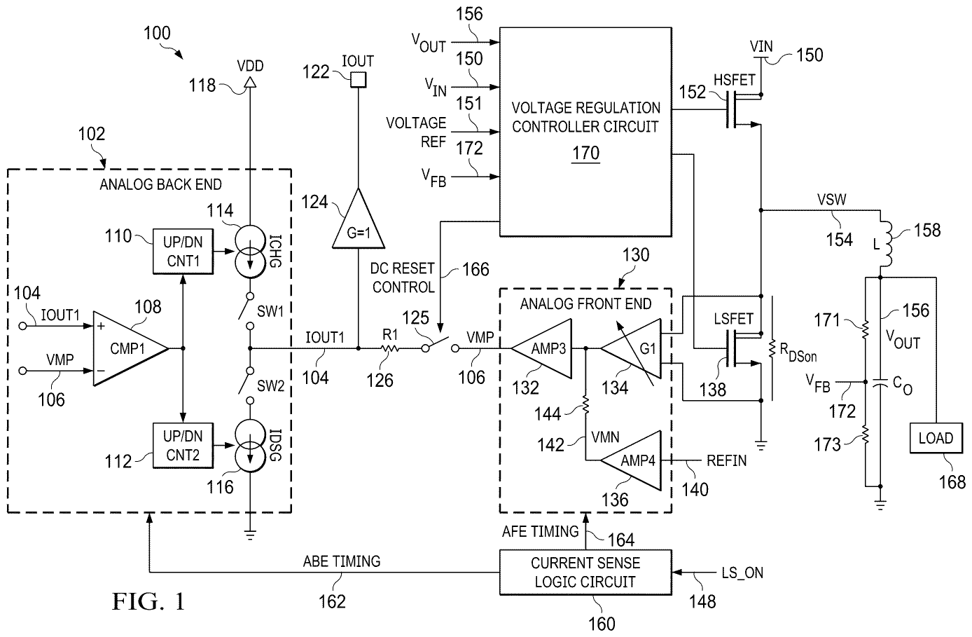

FIG. 1 shows a block diagram for an example buck power converter circuit 100. Buck power converter circuit 100 includes analog back end (ABE) circuit 102, analog front end (AFE) circuit 130, voltage regulation controller circuit 170, high side FET 152, low side FET 138, and current sense logic circuit 160.

The high side FET 152 has a first terminal coupled to and input voltage terminal 150 to receive an input voltage VIN, a second terminal coupled to a switching terminal VSW 154, and a control terminal coupled to a first output of the voltage regulation controller circuit 170. The low side FET 138 has a first terminal coupled to the switching terminal VSW 154, a second terminal coupled to a common (ground) terminal, and a control terminal coupled to a second output of the voltage regulation controller circuit 170. The voltage regulation controller circuit 170 provides control signals to the control terminals (gates) of the high side FET 152 and low side FET 138 to control the alternative switching of these FETs between conductive and nonconductive states (also referred to as ON and OFF states) to regulate an output voltage VOUT at an output 156.

The low side FET 138 has a resistance R_{DSon} which is used to sense the current through the low side FET. An inductor 158 has a first terminal coupled to the switching terminal VSW 154 and a second terminal coupled to the output voltage terminal 156. A filter capacitor C_{O} has a first terminal coupled to the output voltage terminal 156 and a second terminal coupled to the ground terminal.

The example buck power converter circuit 100 is shown as having a single power stage that includes FETs 152, 138, inductor 158, and capacitor C_{O}. In another example, the buck power converter circuit 100 is a multi-phase power converter circuit having multiple such power stages, each referred to as a phase. When implemented as a multi-phase power converter, a phase management circuit is added to the voltage regulation controller circuit 170 to determine when to switch and control switching from single-phase operation to include additional phases. The decision of when to add phases is usually driven by the current demanded by the load on the output.

ABE circuit 102 includes comparator 108, up/down counters 110 and 112, and current sources 114 and 116. An output signal of ABE circuit 102 is IOUT1 104. Comparator 108 has a first input coupled to IOUT1 104 and a second input coupled to the output of AFE circuit 130, VMP 106. The output of comparator 108 is coupled to the input of up/down counter 110 and the input of up/down counter 112. The output of up/down counter 110 is coupled to the control terminal of current source 114. The output of up/down counter 112 is coupled to the control terminal of current source 116. Current source 114 has a first terminal coupled to voltage terminal VDD 118 and a second terminal coupled to the output IOUT1 104 of ABE circuit 102. Current source 116 has a first terminal coupled to the output IOUT1 104 of ABE circuit 102 and a second terminal coupled to a ground terminal.

AFE circuit 130 includes amplifier 134, unity-gain amplifier 132, unity-gain amplifier 136, and resistor 144. Amplifier 134 has a first input coupled to the source of low side FET 138 and a second input coupled to the drain of low side FET 138. Amplifier 134 is a voltage-controlled current source with a variable gain in some examples and a fixed gain in other examples. The output of amplifier 134 is coupled to the input of unity-gain amplifier 132. AFE circuit 130 includes a current sensing circuit with the mechanism to perform an auto-zero operation to cancel the offset error of AFE circuit 130.

Current sense logic circuit 160 has an input that receives a signal LS_ON 148 that indicates when the low side FET 138 is turned on. Current sense logic circuit 160 provides ABE timing signals 162 to ABE circuit 102 and AFE timing signals 164 to AFE circuit 130 which control timing of their respective functions based on the control of the high side FET 152 and low side FET 138 provided by the voltage regulation controller circuit 170.

Voltage regulation controller circuit 170 has inputs 156, 150, and 151 and has outputs coupled to the gates of FETs 152 and 158. Voltage regulation controller circuit 170 includes analog circuitry (e.g., one or more comparators and gate driver circuitry) and digital circuitry or logic (e.g., PWM logic) to control the switching of FETs 152 and 138 to provide the regulated VOUT at output voltage terminal 156. In an example, voltage regulation circuit receives a voltage reference VOLTAGE_{REF} at input 151 that is proportional to the correct regulated voltage and compares it to a feedback voltage V_{FB} at terminal 172 that is proportional to an output voltage VOUT at the output voltage terminal 156. For instance, a resistor divider circuit that includes resistors 171 and 173 is coupled to output voltage terminal 156 to provide a voltage V_{FB} to the input of the voltage regulation controller circuit 170 that is proportion to V_{OUT}. The result of this comparison is provided to a gate drive circuit within voltage regulation controller circuit 170 that provides control signals to the high side FET 152 and the low side FET 138.

AFE circuit 130 performs valley and peak current control by sensing current using R_{DSon}-based current sensing and loop offset correction. ABE circuit 102 creates a ramp signal IOUT1 that emulates the current through inductor 158. The signal IOUT1 at the output 104 of ABE circuit 102 is either a rising ramp to emulate the current through inductor 158 when the low side FET 138 is turned off or is a falling ramp to emulate the current through inductor 158 when the low side FET 138 is turned on. The value of the emulated current IOUT1 is provided as feedback to comparator 108 and is compared to VMP, the actual sensed current. The magnitude of the signal at IOUT1 is adjusted up or down based on a difference between VMP and IOUT1. Depending upon the difference between these two signals, the charge current ICHG will either increase or decrease, or the discharge current IDSG will increase or decrease to emulate the inductor current waveform. The signal IOUT1 at the output 104 of ABE circuit 102 is provided to the input of unity gain amplifier 124, whose output IOUT is provided to the current sense output 122. The input of unity gain amplifier 124 is also coupled to a first terminal of resistor 126.

A second terminal of resistor 126 is coupled to the output of unity-gain amplifier 132 through DC reset switch 125 which turns on following a blanking time after an autozero cycle completes. When low side FET 138 turns on, a timer in voltage regulation controller circuit 170 is triggered. Following a particular time (e.g. 250 ns), voltage regulation controller circuit 170 sends a signal (e.g. logic high) DC Reset Control to close switch 125. Then, when low side FET 138 turns off, voltage regulation controller circuit 170 sends a signal (e.g. logic low) DC Reset Control to open switch 125. IOUT is a voltage proportional to the amount of current flowing through inductor 158. IOUT is provided to voltage regulation controller circuit 170 to help in the determination of when to turn on and turn off low side FET 138.

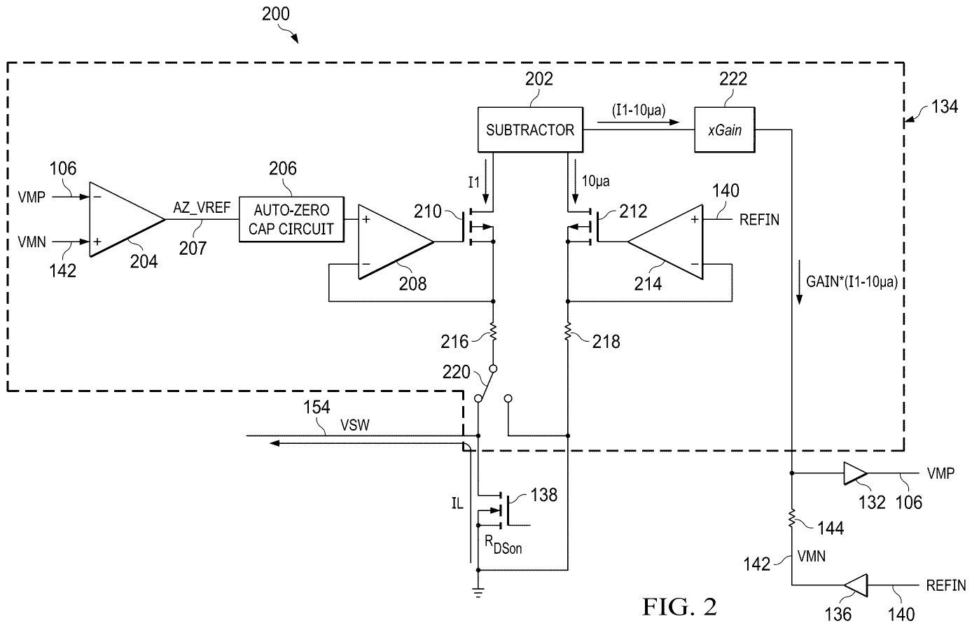

FIG. 2 shows a schematic diagram for an example analog front end (AFE) circuit 200 such as AFE circuit 130 in FIG. 1. AFE circuit 200 includes amplifier 134, unity-gain amplifiers 132 and 136, and resistor 144. Amplifier 134 includes amplifier 204, auto-zero capacitor circuit 206, amplifiers 208 and 214, transistors 210 and 212, subtraction circuit 202, and current amplifier 222.

Amplifier 204 has a first input coupled to terminal 106 and a second input coupled to terminal 142. The output of amplifier 204 is coupled to the input of auto-zero capacitor circuit 206. The output AZ_VREF at terminal 207 of auto-zero capacitor circuit 206 is coupled to a first input of amplifier 208. The output of amplifier 208 is coupled to the control terminal of transistor 210. Amplifier 214 has a first input coupled to a reference terminal REFIN 140. The output of amplifier 214 is coupled to the control terminal of transistor 212.

Transistor 210 has a first terminal coupled to a first input of subtraction circuit 202 and a second input coupled to a second input of amplifier 208. Transistor 212 has a first terminal coupled to a second input of subtraction circuit 202 and a second terminal coupled to a second input of amplifier 214. Resistor 216 has a first terminal coupled to the second input of amplifier 208 and a second terminal coupled to a first terminal of switch 220. Resistor 218 has a first terminal coupled to the second input of amplifier 214 and a second terminal coupled to a second terminal of switch 220. A third terminal of switch 220 is coupled to low side FET 138.

The output of subtraction circuit 202 is coupled to the input of current amplifier 222. The output of current amplifier 222 is coupled to the input of unity-gain amplifier 132. The output of unity-gain amplifier 132 is VMP 106 and is coupled to the first input of amplifier 204. The input of unity-gain amplifier 136 is coupled to the reference terminal REFIN 140. The output of unity-gain amplifier 136 is VMN 142 and is coupled to the second input of amplifier 204. Resistor 144 has a first terminal coupled to the input of unity-gain amplifier 132 and a second terminal coupled to the output of unity-gain amplifier 136.

Subtraction circuit 202 provides at its output a current difference between its two inputs. The first input to subtraction circuit 202 is a corrected sense current I1 that emulates the current through inductor 158. The second input to subtraction circuit 202 is a reference current which in this case is a constant current of 10 uA. The reference current is subtracted from the sense current I1 and the difference is provided to current amplifier 222 which may provide amplification. The output of current amplifier 222 is converted to a voltage by flowing through resistor 144.

The output of current amplifier 222 is coupled to the input of unity-gain amplifier 132. The output of unity-gain amplifier 132 is VMP at terminal 106 that is coupled to the first input of amplifier 204. Reference terminal REFIN 140 is coupled to the input of unity-gain amplifier 136. The output of unity-gain amplifier 136, VMN at terminal 142, is coupled to the second input of amplifier 204. The output of amplifier 204 is an offset voltage. This offset voltage is applied to the auto-zero capacitor circuit 206 which stores the offset voltage. In an example, the auto-zero capacitor circuit is a single capacitor having a first terminal coupled to the output of amplifier 204 and a second terminal coupled to the ground terminal.

Switch 220 controls switching between an auto-zero operation mode and a normal operation mode. During the auto-zero operation, auto-zero capacitor circuit 206 is charged to the correct offset voltage, then that offset voltage is applied as a correction to the sensed current signal during normal operation. The auto-zero operation is performed periodically with a period frequent enough to ensure that the capacitor of auto-zero capacitor circuit 206 does not begin to discharge before the next auto-zero operation. In an example, the auto-zero operation is performed once every 8 PWM cycles. Switch 220 connects resistor 216 to the switching terminal VSW 154 during normal operation and to the ground terminal during the auto-zero operation.

The auto-zero operation determines the offset voltage in the auto-zero loop that includes all the circuitry shown in FIG. 2 and stores that voltage across auto-zero capacitor circuit 206. At the completion of the auto-zero operation, the voltage across auto-zero capacitor circuit 206 is used for the next eight PWM cycles, for example, to cancel the offset voltage. The offset voltage cancellation provided by the auto-zero operation helps improve the accuracy of the current sensing circuit.

When a load transient occurs at the output voltage terminal 156, the output voltage V_{OUT} may suddenly undershoot. In response to that voltage undershoot, the voltage regulation controller circuit 170 may issue additional PWM pulses in quick succession to restore the output voltage more quickly than if the PWM pulses continued on their regular cycle. If a load transient event occurs, the current sense output IOUT 122 is driven by the output of AFE circuit 200, 106, through DC reset switch 125 instead of being driven by emulated output IOUT1 104 of ABE circuit 102, which may not have caught up to the changes in the current through inductor 158 resulting from the load transient event.

If a load transient event occurs while the auto-zero operation is in progress, the auto-zero operation is immediately terminated. When the first additional PWM pulse occurs after a load transient event, the low side FET will be turned off and the high side FET will be turned on. Because the auto-zero operation only occurs while the low side FET is turned on, the auto-zero operation is terminated as soon as the low side FET is turned off. A potential consequence of terminating the auto-zero operation prior to its completion is that the voltage across auto-zero capacitor circuit 206 may not be settled to the correct value to cancel the loop offset, causing a wrong offset voltage to be applied to the circuit for the next eight cycles until the next complete auto-zero operation is performed. This problem can occur particularly when auto-zero capacitor circuit 206 is a single capacitor.

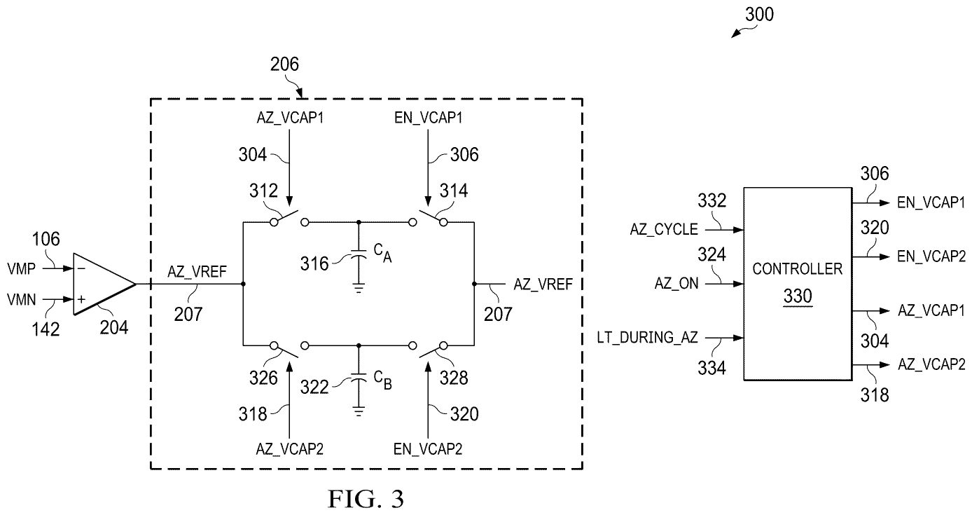

FIG. 3 shows a schematic diagram for an example auto-zero capacitor circuit 300. Auto-zero capacitor circuit 300 includes amplifier 204, switches 312, 314, 326, and 328, controller circuit 330, and capacitors C_{A} 316 and C_{B} 322. Controller circuit 330 may be a sub-circuit of or included in current sense logic circuit 160. Controller circuit 330 receives input signals AZ_CYCLE 332, AZ_ON 324, and LT_DURING_AZ 334 and provides output signals EN_VCAP1 306, EN_VCAP2 320, AZ_VCAP1 304, and AZ_VCAP2 318.

Amplifier 204 has a first input coupled to VMP 106 and a second input coupled to VMN 142. The output of amplifier 204 is coupled to a first terminal of switch 312 which is controlled by the signal AZ_VCAP1 provided by controller circuit 330. The output of amplifier 204 is also coupled to a first terminal of switch 326 which is controlled by the signal AZ_VCAP2 provided by controller circuit 330. A second terminal of switch 312 is coupled to a first terminal of switch 314 which is controlled by the signal EN_VCAP1 306 provided by controller circuit 330. A second terminal of switch 326 is coupled to a first terminal of switch 328 which is controlled by the signal EN_VCAP2 306 provided by controller circuit 330.

Instead of having one capacitor to store the offset voltage, auto-zero capacitor circuit 300 has two capacitors for storing the offset voltage for the current sense loop. During the first eight cycles, capacitor C_{A} 316 is charged to the correct offset voltage and then used to provide the offset voltage correction to amplifier 208 for the next 8 cycles. Capacitor C_{B} 322 is charged to the correct offset voltage during the next 8 cycles and then used to provide the offset voltage correction to amplifier 208 for the next 8 cycles. During normal operation, auto-zero capacitor circuit 300 continues to alternate between capacitor C_{A} 316 and capacitor C_{B} 322 for storing and providing the offset voltage.

If a load transient event occurs during an auto-zero cycle causing the auto-zero operation to be terminated, the voltage on the capacitor being charged may not be correct. So, instead of switching to that capacitor at the end of the 8 cycles, no switching between the two capacitors occurs and the same capacitor will be used for an additional 8 cycles for a total of 16 cycles. In an example, a load transient event is detected by two successive PWM pulses coming too close together. If a load transient occurs during an auto-calibration cycle, the capacitor currently in use will be used for 8 additional cycles instead of using a capacitor that may not be fully charged to the correct loop offset voltage.

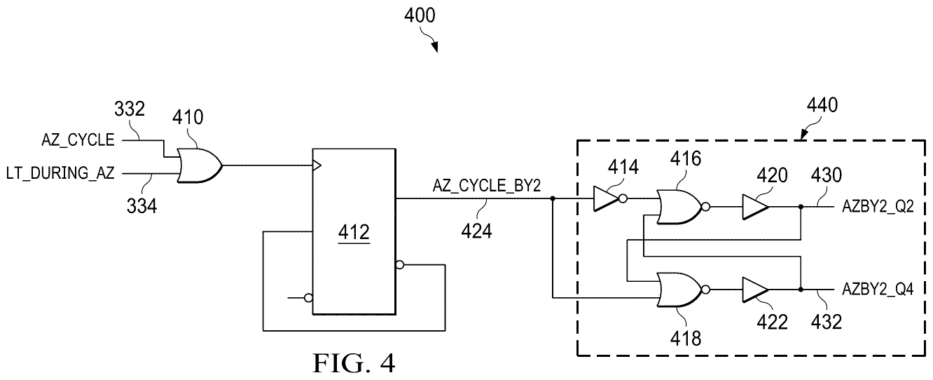

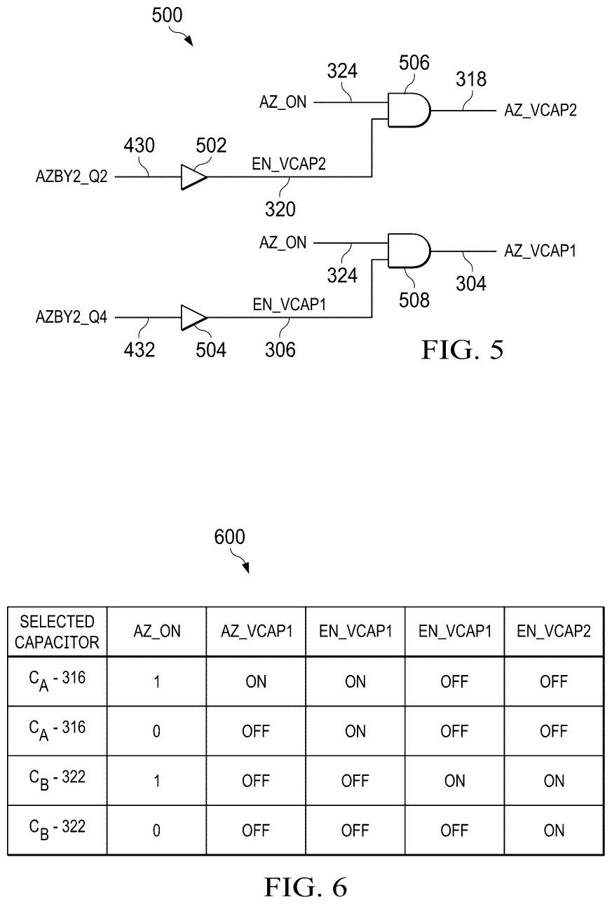

AZ_CYCLE 332 is a signal provided by controller circuit 330 that when high indicates that an auto-zero operation is occurring during the present PWM cycle. An auto-zero operation occurs every fourth PWM cycle in this example. A high on AZ_ CYCLE 332 indicates that the current PWM cycle is an auto-zero cycle. The PWM signal is continuously running during normal operation, and AZ_ CYCLE 332 goes high every fourth cycle of the PWM waveform on the rising edge of the PWM signal. LT_DURING_AZ 334 is a signal that indicates that a load transient occurred during an auto-zero cycle. LT_DURING_AZ 334 goes high if a PWM pulse occurs while AZ_CYCLE 332 is high which indicates that a load transient event has occurred during an auto-zero operation and before the auto-zero operation completed. An example implementation of logic circuitry in controller circuit 330 is shown in FIGS. 4 and 5.

FIG. 4 shows a schematic diagram for an example first logic circuit 400 included in controller circuit 330 for auto-zero capacitor circuit 300. Logic circuit 400 includes OR gate 410, flip-flop 412, and non-overlapping circuit 440. Non-overlapping circuit 440 includes inverter 414, NOR gates 416 and 418, and driver circuits 420 and 422.

OR gate 410 has a first input that receives the signal AZ_CYCLE 332 and a second input that receives the signal LT_DURING_AZ 334. The output of OR gate 410 is coupled to the clock input of flip-flop 412. The data input of flip-flop 412 is coupled to the inverted output of flip-flop 412. The non-inverted output of flip-flop 412 is coupled to the input of non-overlapping circuit 440 and provides the signal AZ_CYCLE_BY2 424. The signal AZ_CYCLE_BY2 424 is the signal AZ_CYCLE 332 with a frequency divided by two so that each rising edge of AZ_CYCLE 332 corresponds to alternating rising and falling edges of AZ_CYCLE_BY2 424.

Non-overlapping circuit 440 has two outputs, AZBY2_Q2 430 and AZBY2_Q4 432, which control the switching between capacitors C_{A} 316 and C_{B} 322, respectively. Non-overlapping circuit 440 helps to ensure that capacitor C_{A} 316 and capacitor C_{B} 322 are not both selected at the same time. It ensures that the switch selecting the first capacitor is turned off prior to the switch selecting the second capacitor being turned on. Non-overlapping circuit 440 takes the signal AZ_CYCLE_BY2 424 as an input and generates signals AZBY2_Q2 430 and AZBY2_Q4 432 that are complementary to each other and having transitions that are separated by a delay created within non-overlapping circuit 440.

In this example, non-overlapping circuit 440 includes an inverter 414 having an input coupled to the noninverting output of flip-flop 412 and receiving the signal AZ_CYCLE_BY2 424. The output of inverter 414 is coupled to a first input of NOR gate 416. The output of NOR gate 416 is coupled to the input of driver circuit 420. The output of driver circuit 420 is coupled to a first input of NOR gate 418. A second input of NOR gate 418 is coupled to the output of flip-flop 412 and receives the signal AZ_CYCLE_BY2 424. The output of NOR gate 418 is coupled to the input of driver circuit 422. The output of driver circuit 420 is AZBY2_Q2 430 and the output of driver circuit 422 is AZBY2_Q4 432. Non-overlapping circuit 440 may be replaced by another non-overlapping circuit topology known in the art.

FIG. 5 shows a schematic diagram for an example second logic circuit 500 included in controller circuit 330 for auto-zero capacitor circuit 300. Logic circuit 500 includes buffer circuits 502 and 504 and AND gates 506 and 508. The input of driver circuit 502 is coupled to the output of driver circuit 420 and receives the signal AZBY2_Q2 430. The input of driver circuit 504 is coupled to the output of driver circuit 422 and receives the signal AZBY2_Q4 432. The output of driver circuit 502 is coupled to the control terminal of switch 328 and provides the signal EN_VCAP2 320.

The first input of AND gate 506 is coupled to the output of driver circuit 502. The second input of AND gate 506 is coupled to controller circuit 330 and receives the signal AZ_ON 324. The signal AZ_ON 324 is a signal that commences the auto-zero cycle. A high on the signal AZ_ON 324 indicates that the auto zero operation is to begin.

FIG. 6 shows a logic truth table 600 for an example auto-zero capacitor circuit. The first column of logic truth table 600 denotes whether capacitor C_{A} 316 or capacitor C_{B} 322 is being selected for the auto-zero operation and storage of the loop offset voltage. The second column of logic truth table 600 denotes whether AZ_ON 324 is high or low. The third column of logic truth table 600 denotes whether AZ_VCAP1 304 is on or off. The fourth column of logic truth table 600 denotes whether EN_VCAP1 306 is on or off. The fifth column of logic truth table 600 denotes whether AZ_VCAP2 318 is on or off. The sixth column of logic truth table 600 denotes whether EN_VCAP2 320 is on or off.

During normal operation, one cycle of auto-zero operation for capacitor C_{A} 316 is followed by 3 cycles of capacitor C_{A} 316 providing the loop offset voltage. This is then followed by one cycle of auto-zero operation for capacitor C_{B} 322, then 3 cycles of capacitor C_{B} 322 providing the loop offset voltage. While the auto-zero operation is being performed with capacitor C_{A} 316, AZ_ON 324 is high, AZ_VCAP1 304 and EN_VCAP1 306 are on, and AZ_VCAP2 318 and EN_VCAP2 320 are off.

While capacitor C_{A} 316 is being used to provide the loop offset voltage, AZ_ON 324 is low, AZ_VCAP1 304 is off, EN_VCAP1 306 is on, and AZ_VCAP2 318 and EN_VCAP2 320 are off. While the auto-zero operation is being performed with capacitor C_{B} 322, AZ_ON 324 is high, AZ_VCAP1 304 and EN_VCAP1 306 are off, and AZ_VCAP2 318 and EN_VCAP2 320 are on. While capacitor C_{B} 322 is being used to provide the loop offset voltage, AZ_ON 324 is low, AZ_VCAP1 304, EN_VCAP2 306 and AZ_VCAP2 318 are off, and EN_VCAP2 320 is on.

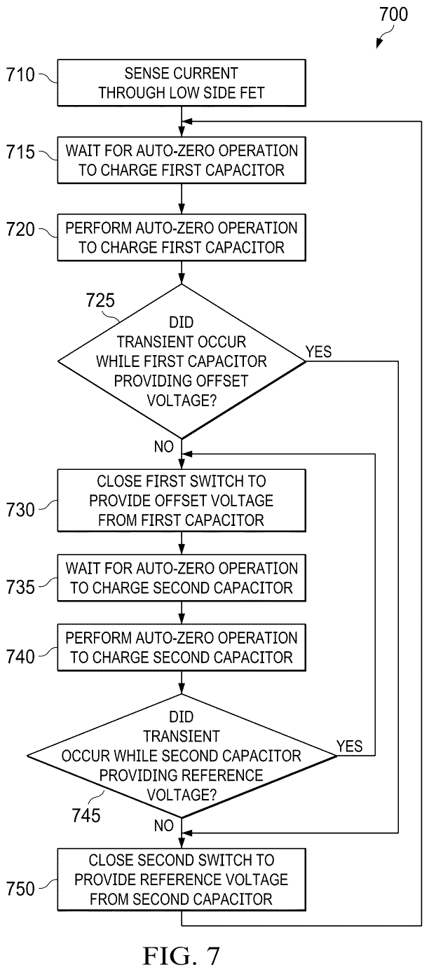

FIG. 7 shows a flow diagram for an example process 700 for operating a current sense circuit using an auto-zero capacitor circuit. In block 710, during voltage regulation, a current through the low side FET is sensed using the R_{DSon} current sensing method. The voltage between the drain and source of the low-side FET 138 is sensed while it is turned on, and the current through the low side FET is derived from dividing the voltage between the drain and source by the on-resistance R_{DSon} of the low side FET 138. Any other current sensing method known in the art may also be used.

In block 715, normal operation continues until the next auto-zero operation is due to be performed. In block 720, an auto-zero operation is performed charging a first capacitor to a voltage equal to an offset voltage in the current sense loop. In block 725, a determination is made whether a load transient event occurred during the auto-zero operation of block 720. This determination may be made by voltage regulation controller circuit 170 or by a system processor (not shown) and is done by monitoring PWM pulses for consecutive pulses too close together. If a load transient event occurs during block 720, the process goes directly to block 750. If no load transient event occurs during block 720, then normal operation continues in block 730. In block 730, a first switch (i.e. 314) is closed providing an offset voltage stored in the first capacitor (i.e. 316). In block 735, normal operation continues until the next auto-zero operation is due to be performed.

In block 740, an auto-zero operation is performed charging the second capacitor (i.e. 322) to a voltage equal to the offset voltage in the current sense loop. In block 745, a determination is made whether a load transient event occurred during the auto-zero operation of block 740. If a load transient event occurred during block 740, the process goes back to block 730 and continues. If no load transient event occurred during block 740, the process proceeds to block 750 and continues. In block 750, a second switch (i.e. 328) is closed providing the offset voltage stored in the second capacitor. The process then returns to block 715.

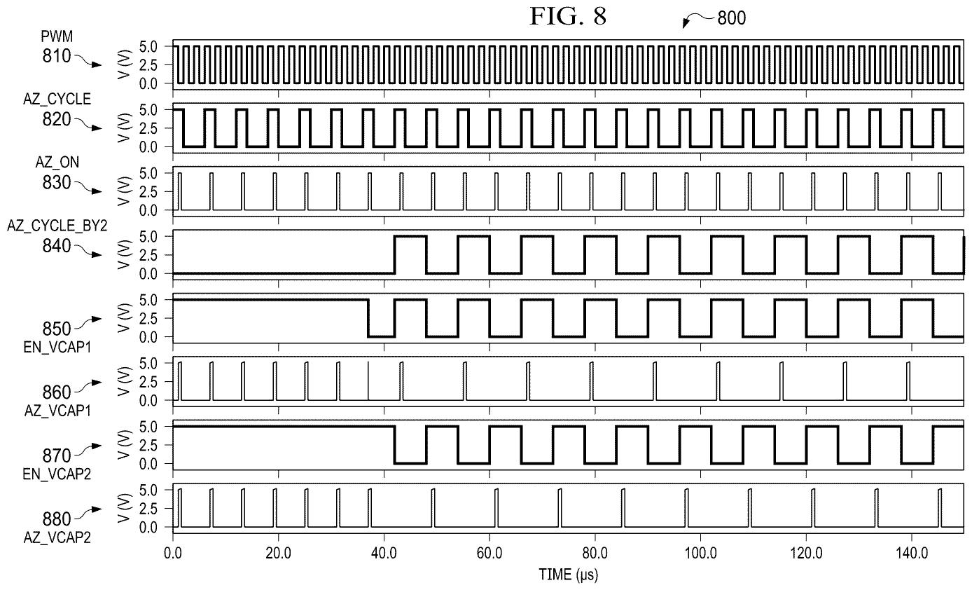

FIG. 8 shows a timing diagram 800 for example signals in the buck power converter circuit 100 including signals controlling the auto-zero capacitor circuit 300 during normal operation with a constant load. Curve 810 is a plot of PWM pulses versus time. Curve 820 is a plot of signal AZ_CYCLE versus time. Curve 830 is a plot of signal AZ_ON versus time. Curve 840 is a plot of signal AZ_CYCLE_BY2 versus time. Curve 850 is a plot of signal EN_VCAP1 versus time. Curve 860 is a plot of signal AZ_VCAP1 versus time. Curve 870 is a plot of signal EN_VCAP2 versus time. Curve 880 is a plot of signal AZ_VCAP2 versus time.

In curve 810, PWM pulses continually occur periodically at a steady frequency when there is a constant load demand. A PWM cycle is from a rising edge of one PWM pulse to the rising edge of the next PWM pulse. AZ_CYCLE is low for three of every four PWM cycles and is high for 1 of every PWM cycles. In some cases, AZ_CYCLE may occur once every eight PWM cycles instead of four PWM cycles. AZ_CYCLE being high indicates that an auto-zero operation is in progress. The auto-zero operation will alternate between charging capacitor C_{A} 316 and capacitor C_{B} 322. One AZ_ON pulse occurs for each auto-zero cycle and initiates the auto-zero operation to begin.

AZ_CYCLE_BY2 is a divide by two of the frequency of AZ_CYCLE and controls which of the two capacitors is used for that particular auto-zero cycle. AZ_CYCLE_BY2 changes polarity on every rising edge of AZ_CYCLE. So, if AZ_CYCLE_BY2 goes high on a first rising edge of AZ_CYCLE, it goes low on the next rising edge of AZ_CYCLE. AZ_CYCLE_BY2 is used to switch back and forth between selecting capacitor C_{A} 316 and capacitor C_{B} 322. Capacitor C_{A} 316 will be used if AZ_CYCLE_BY2 is high and capacitor C_{B} 322 will be used if AZ_CYCLE_BY2 is low.

AZ_VCAP1 and AZ_VCAP2 each have the same frequency and coincide with each other. EN_VCAP1 and EN_VCAP2 have the same frequency and opposite polarity from each other. EN_VCAP1 is high when AZ_CYCLE_BY2 is high and controls switch. EN_VCAP2 is high when AZ_CYCLE_BY2 is low and controls switch. EN_VCAP1 and EN_VCAP2 are never high at the same time to avoid selecting both capacitor C_{A} and capacitor C_{B} simultaneously because this could lead to undesirable effects on the circuit. During normal operation with a constant load, PWM, AZ_CYCLE, AZ_ON, AZ_CYCLE_BY2, EN_VCAP1, and EN_VCAP2 all run at a constant frequency and have a constant period.

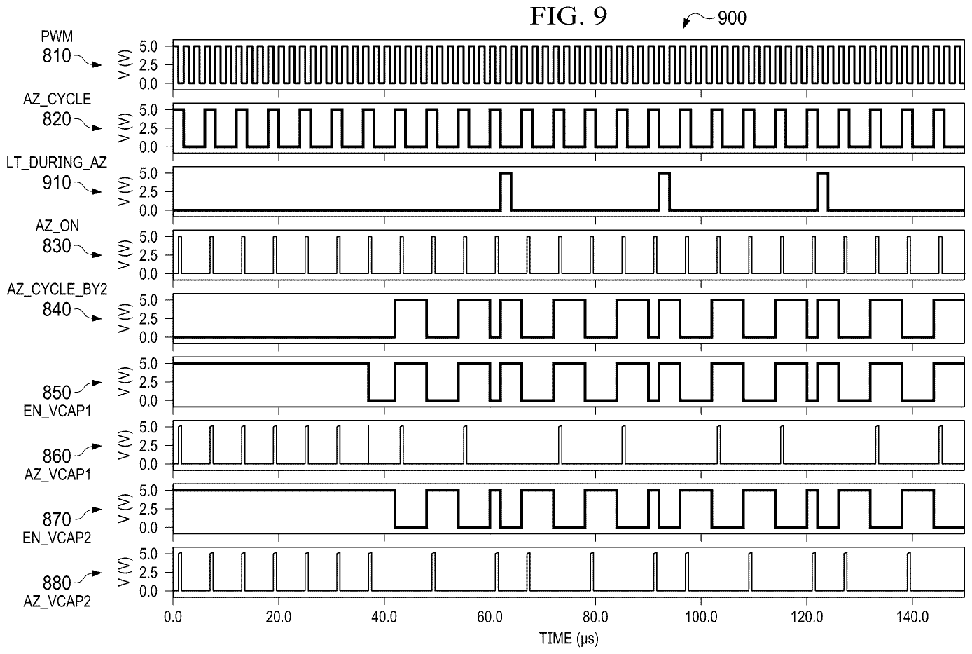

FIG. 9 shows a timing diagram 900 for example signals in the buck power converter circuit 100 including signals controlling the auto-zero capacitor circuit 300 during a load transient event. Curve 810 is a plot of PWM pulses versus time. Curve 820 is a plot of AZ_CYCLE versus time. Curve 910 is a plot of LT_DURING_AZ versus time. Curve 830 is a plot of AZ_ON versus time. Curve 840 is a plot of AZ_CYCLE_BY2 versus time. Curve 850 is a plot of EN_VCAP1 versus time. Curve 860 is a plot of AZ_VCAP1 versus time. Curve 870 is a plot of EN_VCAP2 versus time. Curve 880 is a plot of AZ_VCAP2 versus time.

Operation in FIG. 9 is the same as operation in FIG. 8 until a load transient occurs in the circuit and the first high pulse occurs on LT_DURING_AZ indicating that a load transient has occurred during an auto-zero operation. A load transient results in a burst of additional PWM pulses being issued to attempt to remedy a drop in V_{OUT} (not shown), which makes PWM no longer runs at a constant frequency during this burst of additional PWM pulses. In curve 910, each time that a high pulse occurs on LT_DURING_AZ indicates that a separate load transient occurred during an auto-zero operation. When this occurs, the auto-zero operation is terminated before the auto-zero cycle completes. When LT_DURING_AZ goes high, AZ_CYCLE is pulled low which disrupts the toggling of AZ_CYCLE_BY2 424 which is a frequency divide by two of AZ_CYCLE.

When LT_DURING_AZ goes high, the effect will be to toggle from the currently selected capacitor to the other capacitor. When LT_DURING_AZ goes high, AZ_CYCLE_BY2 changes polarity instead of waiting to change polarity at the next auto-zero cycle. That capacitor is then used until the next auto-zero cycle. In this example, the cycle for capacitor C_{B} 322 is cut short by the LT_DURING_AZ causing EN_VCAP1 to be pulled high early, switching back to capacitor C_{A} 316 as the selected capacitor. When a load transient occurs during an auto-zero operation, PWM, AZ_CYCLE, AZ_ON, AZ_CYCLE_BY2, EN_VCAP1, and EN_VCAP2 do not run at a constant frequency and have a constant period while the transient is causing extra PWM pulses. Normal operation will resume at the next auto-zero cycle if no additional high signals on LT_DURING_AZ occur.

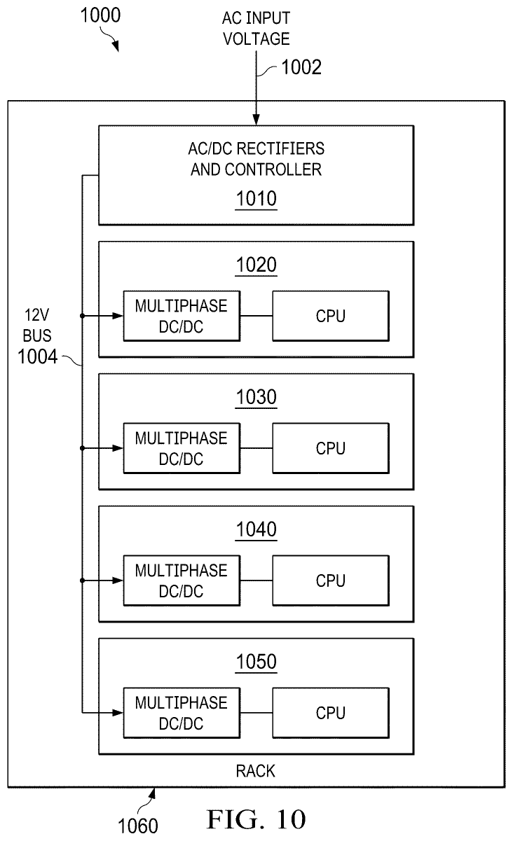

FIG. 10 shows a block diagram for an example power supply system 1000 with multiphase DC-DC converters. Power supply system 1000 includes a rack 1060. Rack 1060 includes slots or trays 1020, 1030, 1040 and 1050. Each slot contains a circuit board having a multiphase DC-DC power converter and a central processing unit (CPU). Rack 1060 also includes AC-DC rectifier and controller 1010. In an example,

AC-DC rectifier and controller 1010 receives an AC input voltage 1002 and converts that AC voltage to a DC voltage (i.e. 12 VDC) and provides the DC voltage on 12V bus 1004. Slots 1020, 1030, 1040 and 1050 are each connected to 12V bus 1004 and receive the 12V bus voltage as an input. The multiphase DC-DC power converter in each slot converts the input voltage to a DC voltage usable for powering the CPU on its circuit board (e.g. 12V to 5V). The DC voltage output from each respective DC-DC power converter is provided to the respective CPU on its circuit board. Each respective DC-DC power converter includes an auto-zero capacitor circuit 300.

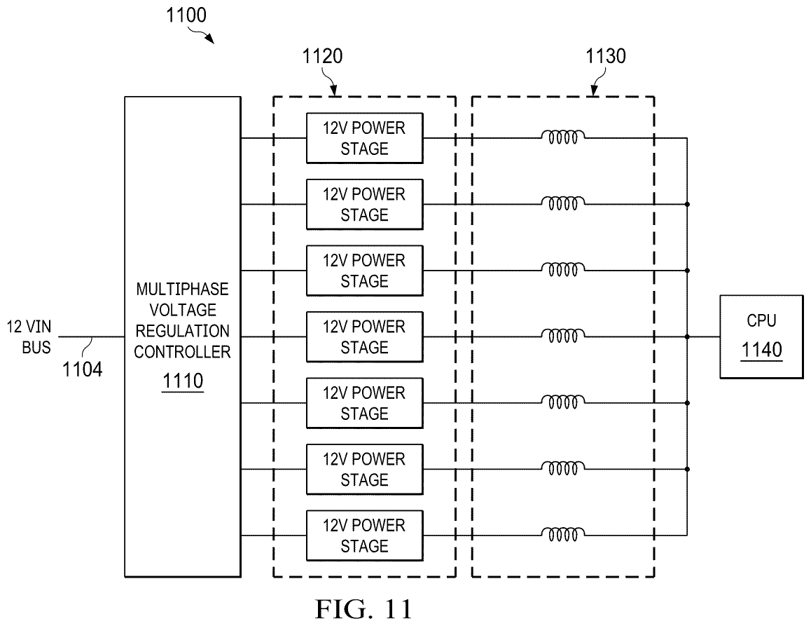

FIG. 11 shows a block diagram for an example multiphase power converter system 1100. Multiphase power converter system 1100 includes multiphase voltage regulation controller 1110, 12V power stages 1120, inductors 1130, and CPU 1140. The input of multiphase voltage regulation controller 1110 is coupled to 12V bus 1104. Multiphase voltage regulation controller 1110 has multiple outputs, each output coupled to the input of a respective 12V power stage 1120. The output of each respective 12V power stage 1120 is coupled to a first terminal of a respective inductor 1130. The second terminal of each respective inductor 1130 is coupled to CPU 1140.

Each respective 12V power stage 1120 of multiphase power converter system 1100 includes an auto-zero capacitor circuit 300. Multiphase power converter system 1100 may be used in servers or large computing systems. Examples where multiphase power converter system 1100 may be used include data storage centers, graphical processing units, and artificial intelligence (AI) data centers.

In this description, “terminal,” “node,” “interconnection,” “lead” and “pin” are used interchangeably. Unless specifically stated to the contrary, these terms generally mean an interconnection between or a terminus of a device element, a circuit element, an integrated circuit, a device, or other electronics or semiconductor component.

In this description, “ground” includes a chassis ground, an Earth ground, a floating ground, a virtual ground, a digital ground, a common ground and/or any other form of ground connection applicable to, or suitable for, the teachings of this description.

In this description, the term “couple” may cover connections, communications or signal paths that enable a functional relationship consistent with this description. For example, if device A generates a signal to control device B to perform an action, then: (a) in a first example, device A is coupled to device B by direct connection; or (b) in a second example, device A is coupled to device B through intervening component C if intervening component C does not alter the functional relationship between device A and device B, so device B is controlled by device A via the control signal generated by device A.

In this description, even if operations are described in a particular order, some operations may be optional, and the operations are not necessarily required to be performed in that particular order to achieve specified results. In some examples, multitasking and parallel processing may be advantageous. Moreover, a separation of various system components in the embodiments described above does not necessarily require such separation in all embodiments.

Modifications are possible in the described embodiments, and other embodiments are possible, within the scope of the claims.

What is claimed is:

1. A circuit, comprising:
a controller having first, second, third and fourth outputs;
an amplifier having first and second inputs and an output;
a switched capacitor circuit that includes:
a first switch having first and second terminals and a control terminal, the first terminal coupled to the output of the amplifier, the control terminal coupled to the first output of the controller;
a second switch having first and second terminals and a control terminal, the first terminal coupled to the second terminal of the first switch, the control terminal coupled to the second output of the controller;
a third switch having first and second terminals and a control terminal, the first terminal coupled to the output of the amplifier, the control terminal coupled to the third output of the controller;
a fourth switch having first and second terminals and a control terminal, the first terminal coupled to the second terminal of the third switch, the control terminal coupled to the fourth output of the controller, and the second terminal coupled to the second terminal of the second switch;
a first capacitor having a first terminal coupled to the first terminal of the second switch and a second terminal coupled to a ground terminal; and
a second capacitor having a first terminal coupled to the first terminal of the fourth switch and a second terminal coupled to the ground terminal.

2. The circuit of claim 1, wherein the first, third and fourth switches are open and the second switch is closed during a first regular operation cycle.

3. The circuit of claim 2, wherein the first and second switches are closed and the third and fourth switches are open during a first offset correction cycle.

4. The circuit of claim 3, wherein the first, second and third switches are open and the fourth switch is closed during a second regular operation cycle.

5. The circuit of claim 4, wherein the first and second switches are open and the third and fourth switches are closed during a second offset correction cycle.

6. The circuit of claim 4, wherein the first capacitor and the second capacitor alternate in providing an offset correction voltage equal to a loop offset voltage.

7. The circuit of claim 5, wherein the circuit is included in a power converter, and the first offset correction cycle or the second offset correction cycle is terminated early in response to a load transient on an output of the power converter.

8. A circuit, comprising:
a controller having first, second, third and fourth outputs;
a first amplifier having first and second inputs and an output, the first input coupled to a voltage terminal; and
a switched capacitor circuit that includes:
a first switch having first and second terminals and a control terminal, the first terminal coupled to the output of the first amplifier, the control terminal coupled to the first output of the controller;
a second switch having first and second terminals and a control terminal, the first terminal coupled to the second terminal of the first switch, the control terminal coupled to the second output of the controller;
a third switch having first and second terminals and a control terminal, the first terminal coupled to the output of the first amplifier, the control terminal coupled to the third output of the controller;
a fourth switch having first and second terminals and a control terminal, the first terminal coupled to the second terminal of the third switch, the control terminal coupled to the fourth output of the controller, and the second terminal coupled to the second terminal of the second switch;
a first capacitor having a first terminal coupled to the first terminal of the second switch and a second terminal coupled to a ground terminal; and
a second capacitor having a first terminal coupled to the first terminal of the fourth switch and a second terminal coupled to the ground terminal;
a second amplifier having an input and an output, the input coupled to the second terminal of the fourth switch;
a third amplifier having an input and an output, the input coupled to the voltage terminal;
a subtractor having first and second inputs and an output, the first input coupled to the output of the second amplifier, the second input coupled to the output of the third amplifier; and
a fourth amplifier having an input and an output, the input coupled to the output of the subtractor, the output coupled to the second input of the first amplifier.

9. The circuit of claim 8, further comprising a fifth amplifier having an input and an output, the input coupled to the output of the fourth amplifier, the output coupled to the second input of the first amplifier.

10. The circuit of claim 8, wherein the first, third and fourth switches are open and the second switch is closed during a first regular operation cycle.

11. The circuit of claim 10, wherein the first and second switches are closed and the third and fourth switches are open during a first offset correction cycle.

12. The circuit of claim 11, wherein the first, second and third switches are open and the fourth switch is closed during a second regular operation cycle.

13. The circuit of claim 12, wherein the first and second switches are open and the third and fourth switches are closed during a second offset correction cycle.

14. The circuit of claim 12, wherein the first capacitor and the second capacitor alternate in providing an offset correction voltage equal to a loop offset voltage.

15. The circuit of claim 13, wherein the circuit is included in a power converter, and the first offset correction cycle or the second offset correction cycle is terminated early in response to a load transient on an output of the power converter.

16. A system, comprising:
a multiphase voltage regulation controller having an input and multiple outputs;
multiple power stages, each respective power stage having an input and an output, each respective input coupled to a respective output of the multiphase voltage regulation controller, each respective power stage including:
a controller having first, second, third and fourth outputs;
an amplifier having first and second inputs and an output;
a switched capacitor circuit that includes:
a first switch having first and second terminals and a control terminal, the first terminal coupled to the output of the amplifier, the control terminal coupled to the first output of the controller;
a second switch having first and second terminals and a control terminal, the first terminal coupled to the second terminal of the first switch, the control terminal coupled to the second output of the controller;
a third switch having first and second terminals and a control terminal, the first terminal coupled to the output of the amplifier, the control terminal coupled to the third output of the controller;
a fourth switch having first and second terminals and a control terminal, the first terminal coupled to the second terminal of the third switch, the control terminal coupled to the fourth output of the controller, and the second terminal coupled to the second terminal of the second switch;
a first capacitor having a first terminal coupled to the first terminal of the second switch and a second terminal coupled to a ground terminal; and
a second capacitor having a first terminal coupled to the first terminal of the fourth switch and a second terminal coupled to the ground terminal;
multiple inductors, each respective inductor having a first terminal and a second terminal, each respective first terminal coupled to a respective output of a power stage; and
a processor having an input, the input coupled to each of the respective second terminals of the multiple inductors.

17. The system of claim 16, wherein the first, third and fourth switches are open and the second switch is closed during a first regular operation cycle.

18. The system of claim 17, wherein the first and second switches are closed and the third and fourth switches are open during a first offset correction cycle.

19. The system of claim 18, wherein the first, second and third switches are open and the fourth switch is closed during a second regular operation cycle.

20. The system of claim 19, wherein the first and second switches are open and the third and fourth switches are closed during a second offset correction cycle.

21. The system of claim 19, wherein the first capacitor and the second capacitor alternate in providing an offset correction voltage equal to a loop offset voltage.
